(19) United States
(12) Patent Application Publication
(10) Pub. No.: US 2006/0232931 A1
(43) Pub. Date: Oct. 19, 2006

(54) Fan for ventilating electrical and electronic equipment

(75) Inventor: Robert Obermaier, Egglham (DE)

Correspondence Address: O'Shea, Getz & Kosakowski, P.C., Suite 912, 1500 Main Street, Springfield, MA, 01115, US

(73) Assignee: Harman Becker AUTOMOTIVE Systems GmbH

(21) Appl. No.: 11/398,487

(22) Filed: Apr. 5, 2006

(30) Foreign Application Priority Data
Apr. 7, 2005 (EP) 05 007 648.8

(51) Int. Cl. H05K 7/20

(52) U.S. Cl. 361/695

(57) ABSTRACT

A fan for ventilating electrical and electronic equipment includes a fan housing adapted to be plugged in a printed circuit board and having a duct for allowing air to flow. The fan housing is positioned substantially upright with respect to the printed circuit board. The duct has a fan wheel of a fan arranged therewithin. An electric motor is coupled to the fan housing for driving the fan wheel. At least three fasteners are coupled to at least part of the fan housing for fixing the fan on the printed circuit board. A power supply adapter, which is coupled to at least part of the fan housing, includes connectors that provide electrical connection to the printed circuit board for supplying power to the electric motor.

### CLAIM OF PRIORITY

This patent application claims priority to European Patent Application serial number 05 007 648.8 filed on Apr. 7, 2005.

1. Field of the Invention

This invention relates in general to heat dissipation in equipment, and in particular to a fan for ventilating electrical and electronic equipment.

2. Related Art

Electrical or electronic equipment generates heat during its operation due to thermal power loss. Electrically powered fans for removing the generated heat are well known. Typical examples of such fans are disclosed in U.S. Published Patent Application 2004-0096325; U.S. Pat. No. 5,267,842; U.S. Pat. No. 6,013,966; German Patent 100 20 878 C2; and German Published Patent Application 195 03 521 A1.

Generally, this type of fan comprises a fan housing, a fan wheel connected to the fan housing, and an electric motor that powers the fan wheel. Typically, the fan wheel rotates in a flow duct formed by the fan housing. The air flow in the electrical or electronic equipment is primarily controlled by the design of the flow duct and the arrangement of the fan wheel therein. For cooling purposes, the fan introduces fresh air into the electric or electronic equipment, dissipates warm air from that equipment, and/or circulates the air inside that equipment in closed circuits. Usually, the fan is arranged in a part of the housing of the electronic equipment or adjacent to the electronic components that need cooling. The mechanical connection for the fan is typically achieved by screws or clamp connections. The electronic components to be cooled are conventionally mounted on a printed circuit board (PCB). The electric power required for powering the electric motor usually comes from a cable connection, which is either a flexible line equipped with an electrical connector that can connect to, for example, a PCB or a fixed cable soldered to the PCB.

The conventional fan has several disadvantages. For example, the cable connection to the power supply requires an additional production step and therefore increases the production cost. In addition, there exists a risk of damaging the equipment by crushing or tearing the cables. Furthermore, depending on the connection used, there may be a risk of reversing the polarity of the fan by interchanging the connection lines during the manufacturing process.

German Published Patent Application DE 101 01 348 A1 describes a fan powered by an electric drive motor and equipped with electrical wrap connections for obtaining power from a PCB. This known fan, however, overcomes only part of the above described disadvantages. Although the wrap connection may be better than a flexible line or a soldered cable in certain ways, the fan disclosed in that patent application nevertheless suffers from other problems. One problem is that the contacts designated for the wrap connection are relatively thin because they are intended to directly connect to the conducting paths located on the PCB. Another problem is that, since the fan is positioned substantially perpendicular to the PCB, the stability of the fan, whether during mounting or during operation, is of concern.

There is a need for a fan free of the aforementioned problems. Specifically, there is a need for a relatively stable configuration for the fan and a relatively reliable connection for the fan's power supply. Since cooling of electric and electronic equipment is also important in automotive applications, the fan of the present invention is useful for such applications.

### SUMMARY OF THE INVENTION

A fan includes a fan housing adapted to be plugged in a PCB and having a duct for allowing air to flow. Longer edges of the fan housing are positioned at a substantially parallel position with respect to the PCB. For example, the fan housing may be positioned such that the axis of the duct of the fan housing is substantially perpendicular to the PCB. The duct has a fan wheel arranged therewithin, and an electric motor is coupled to the fan housing for powering the fan wheel. The fan also includes a plurality of fasteners that are coupled to at least part of the fan housing for fixing the fan onto the PCB. The fan also includes a power supply adapter coupled to at least part of the fan housing. The power supply adapter, which is pluggable, includes a connector for providing electrical connection to the PCB for supplying power to the electric motor.

Advantangeously, the fan has improved stability due to the use of the fasteners and the substantially parallel position of the longer edges of the fan housing with respect to the PCB. For example, the fan housing may be positioned such that the axis of the duct of the fan housing is substantially perpendicular to the PCB, and the plurality of fasteners secure the fan to the PCB (e.g., at the edges of the fan housing). Another advantage is that the power supply adapter is also relatively stable, because it is fixed to the fan housing at one end, connects with the PCB at the other end, and extends axially downward the fan housing to reach the PCB. The power supply adapter may be fixed to the outside wall of the fan housing, or it may be part of the fan housing, both providing a relatively stable arrangement. Yet another advantage is that the power supply adapter provides a relatively reliable connection to the PCB. When the power supply adapter extends axially downward the fan housing, the width of the power supply adapter is not restricted to a relatively large extent. The constraint for the width of the contacts for electrical connection with the PCB is substantially eliminated. Unlike the conventional fan construction, such as in the aforementioned German Published Patent Application DE 101 01 348 A1, according to an aspect of the present invention, the electrical contacts with the PCB do not have to be coupled with conducting paths on the PCB. Thus, the contacts do not need to be relatively thin. This advantage reduces the risk of damaging the contacts.

The present invention provides a fan for ventilating electrical and electronic equipment, where the fan has a relatively stable configuration and a relatively reliable connection to the power supply.

The other systems, methods, features and advantages of the invention will be, or will become, apparent to one with skill in the art upon examination of the following figures and detailed description. It is intended that all such additional systems, methods, features and advantages be included within this description, be within the scope of the invention, and be protected by the following claims.

### DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like reference numerals designate corresponding parts throughout the different views.

FIG. 1 is a perspective view of a fan;

FIG. 2 is a top plan view of the fan; and

FIG. 3 is a side view of the fan.

### DETAILED DESCRIPTION

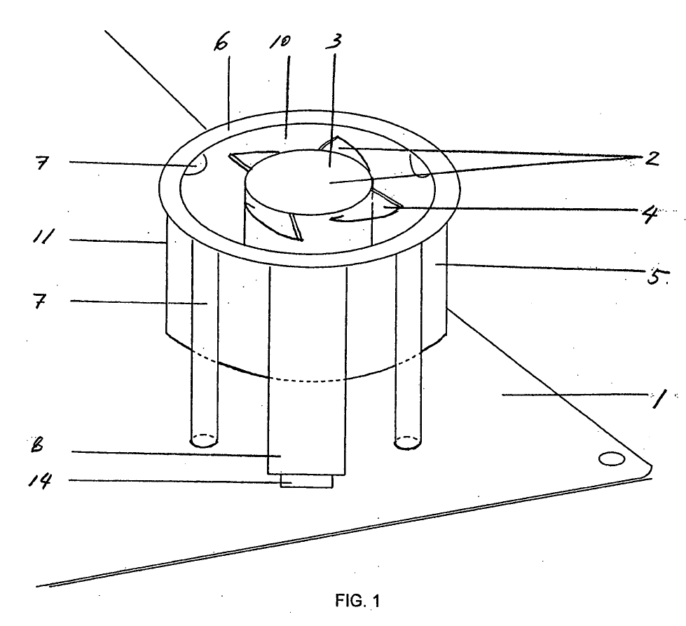

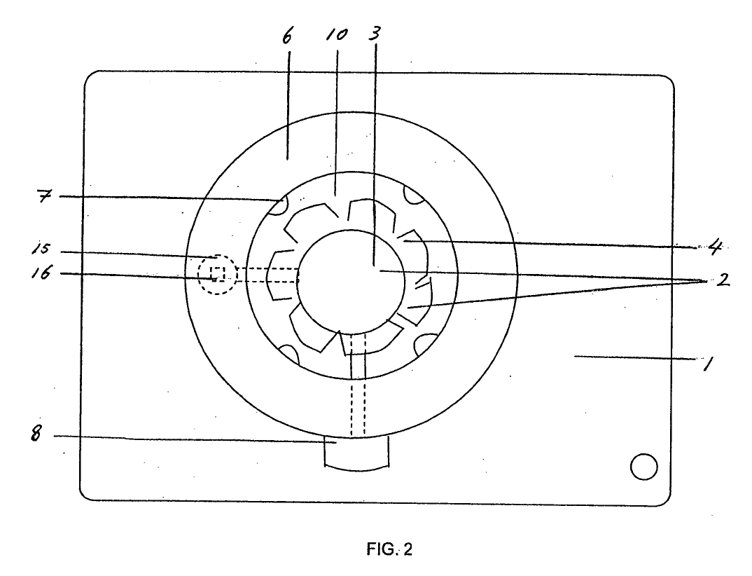

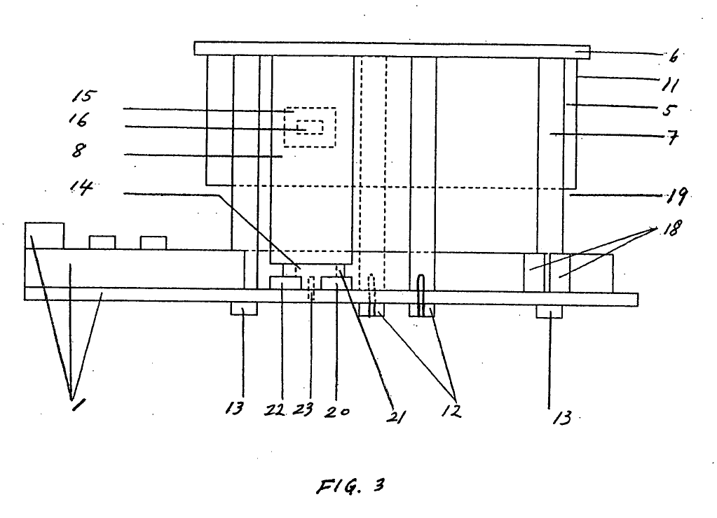

The fan of FIGS. 1-3 comprises a fan housing 5 that is adapted to be plugged into a PCB 1. The fan housing 5 not only acts as a housing, but also provides a duct 10 for directing air flow. The longer edges of the fan housing 5 are in a substantially parallel position with respect to the PCB 1. For example, the fan housing 5 may be positioned such that the axis of the duct of the fan housing is substantially perpendicular to the PCB 1. The fan housing 5 may be constructed as a cylindrical tube. The intersection of the duct 10 with the external environment may be substantially parallel to the PCB 1. A fan wheel 2, which includes a hub 3 and rotor blades 4, rotates within the flow duct 10. The fan wheel 2 is powered by an electric drive motor 15 located in an inner center portion of the fan housing 5. The dimensions of the flow duct 10 depend on the radius of the fan wheel 2, or, in particular, the radius of the rotor blades 4, which in turn depend on the specific application of the fan and the air flow required. The rim of the duct 10 is constructed as a flange 6 which may serve as a base for a fastener that secures the fan onto the PCB 1. The flange 6 may be an outward-bended flange.

The fan of FIGS. 1-3 further includes a plurality of fasteners 7 that secure the fan onto the PCB 1. In principle, any kind of fasteners can be used for the present invention. In the fan shown in FIGS. 1-3, the fasteners 7 are columnar supports members. At least three fasteners 7 (four of such fasteners 7 are shown in the example of FIGS. 1-3) are directly connected to at least part of the fan housing 5, such as to the flange 6. There are several ways to achieve this connection: the fasteners 7 may be connected solely to the flange 6; or, for a more stable connection, the fasteners 7 may be also connected to some other parts of the fan housing 5, such as an outside wall 11 thereof; furthermore, the fasteners 7 may be an integrated part of the fan housing 5.

The fasteners 7, which extend downward the fan housing 5 to reach the PCB 1, are equipped with mounting elements 12, 13 for connection with the PCB 1. The mounting elements 12, 13 directly connect the fasteners 7 with the PCB 1. Any kind of mounting mechanisms can be used for this invention. For example, pluggable mounting mechanisms may be used because they allow the fasteners 7 to easily plug into corresponding connection units 18 of the PCB 1 and stay securely therewithin. The corresponding connection units 18 may be recesses in the PCB 1. More specific examples of the mounting mechanisms include wrap connections, snap connections, and the like. For easy connection, at least two snap connections may be used. FIGS. 1-3 show snap connections. The axial length of the mounting mechanisms 12, 13 may be selectable, so that a gap 19 may be created between the PCB 1 and the fan housing 5. A sufficient gap 19 promotes increased air flow and enhances the overall efficiency of the cooling system.

The fan of FIGS. 1-3 further comprises a power supply, which includes the electric drive motor 15 and a power supply adapter 8. The power supply adapter 8 may be connected to the fan housing 5 as well as the PCB 1. The electric drive motor 15 may be securely connected to the fan housing 5 or may be directly connected to the hub 3. The power for the electric drive motor 15 is supplied by the power supply adapter 8, which is connected to at least part of the fan housing 5 and is adapted to provide connections to the PCB 1. There are several ways to connect the power supply adapter 8 to the fan housing 5. The power supply adapter 8 may be connected solely to the flange 6, as shown in FIGS. 1-3. For a more stable connection, the adapter 8 may be also connected to some other parts of the fan housing 5, such as the outside wall 11. Furthermore, the adapter 8 may be an integrated part of the fan housing 5.

The power supply adapter 8 extends axially downward the fan housing 5 to reach the PCB 1. In this way, the width of the power supply adapter 8 is not restricted to any relatively large extent. With respect to its connection with the PCB 1, the power supply adapter 8 may have a wrap connection 14 for this purpose. Any kinds of wrap connection may be used, one example being the pluggable wrap connection which allows a relatively easy and secure connection. The wrap connection 14 may be integrated in a substantially closed connector housing 21, so that the contacts of the wrap connection 14 are protected both during the manufacturing process and the actual operation of the fan. The wrap connection 14, and its housing 21, if any, may be adapted to match corresponding connection units 20, 22 on the PCB 1. Both connection units 20, 22 may be constructed in a way that facilitates a relatively easy and reliable plugging between the two units without any additional effort, such as soldering or the like. The power supply adapter 8 may also be combined with a mechanical clamp connection 23 to provide additional locking for the electrical connection.

Due to the relatively unrestricted width of the power supply adapter 8, the present invention substantially eliminates the constraint for the width of the contacts designated for the electrical connection with the PCB 1. Unlike the conventional fan construction, such as in the aforementioned German Published Patent Application DE 101 01 348 A1, the electrical contacts with the PCB 1 of the present invention do not have to be coupled with some conducting paths on the PCB 1. Thus, these contacts do not need to be made relatively thin. This advantage substantially reduces the risk of damaging the contacts.

As an additional advantage, the electronics 16 of the electric drive motor 15, such as filters, et cetera, may be integrated into the power supply adapter 8. Such an arrangement provides an advantage of reducing the size of the electric drive motor 15.

Although an example of this invention has been described hereinabove in detail, it is desired to emphasize that this has been for the purpose of illustrating the invention and should not be considered as necessarily limitative of the invention, it being understood that many modifications and variations can be made by those skilled in the art while still practicing the invention claimed herein.

What is claimed is:

1. A fan for ventilating electrical and electronic equipment, comprising:
a fan housing adapted to be plugged in a printed circuit board and having a duct for allowing air to flow, longer edges of the fan housing being positioned parallel with respect to the printed circuit board;
a fan having a fan wheel arranged in the duct;
an electric motor coupled to the fan housing for driving the fan wheel;
at least three fasteners coupled to at least part of the fan housing for securing the fan on the printed circuit board; and
a power supply adapter coupled to at least part of the fan housing, the power supply adapter having connectors for providing electrical connection to the printed circuit board for supplying power to the electric motor.

2. The fan of claim 1, where the fan housing is positioned such that the longitudinal axis of the duct is substantially perpendicular to the printed circuit board.

3. The fan of claim 2, where the duct has a flange that provides a base for the fasteners.

4. The fan of claim 3, where the flange is outward-bended.

5. The fan of claim 1, where the fan housing comprises a cylindrical tubular housing with its inner diameter adapted to the radius of the fan wheel.

6. The fan of claim 5, where the fan is mounted on the cylindrical tubular housing.

7. The fan of claim 6, where the electric motor is arranged in an inner center portion of the cylindrical tube housing of the fan housing.

8. The fan of claim 3, where the fasteners are fixed to the flange at one end and have a mounting mechanism at the other end for connection with the printed circuit board.

9. The fan of claim 8, where the fasteners are fixed to the outside wall of the fan housing.

10. The fan of claim 8, where the fasteners are an integral part of the fan housing.

11. The fan of claim 8, where the fasteners comprise columnar support members that extend axially downward the fan housing.

12. The fan of claim 11, where the columnar support members extend downward the fan housing such that there is a sufficient gap between the fan housing and the printed circuit board for exhausting air from the printed circuit board.

13. The fan of claim 12, where the mounting mechanism of the fasteners are adapted to corresponding connection units on the printed circuit board.

14. The fan of claim 13, where the connection units comprise recesses in the printed circuit board.

15. The fan of claim 13, where at least two of the mounting mechanisms are snap connections.

16. The fan of claim 3, where the power supply adapter is fixed to the flange at one end and has at least one connecting mechanism at the other end for connecting with the printed circuit board.

17. The fan of claim 16, where the power supply adapter is secured to the outside wall of the fan housing.

18. The fan of claim 16, where the power supply adapter is an integral part of the fan housing.

19. The fan of claim 16, where the power supply adapter axially extends downward the fan housing.

20. The fan of claim 16, where the at least one connecting mechanism of the power supply adapter comprises a wrap connection.

21. The fan of claim 20, where the wrap connection is pluggable so as to match a corresponding connection unit on the printed circuit board.

22. The fan of claim 21, where the connection unit comprises a recess in the printed circuit board.

23. The fan of claim 20, where the wrap connection is integrated in a substantially closed connector housing.

24. The fan of claim 23, where the closed connector housing is adapted to match a corresponding connection unit on the printed circuit board.

25. The fan of claim 24, where the connection unit comprises a recess in the printed circuit board.

26. The fan of claim 3, where the power supply adapter comprises a mechanical clamp, connection for ensuring the electrical connection to the printed circuit board.

27. The fan of claim 3, where electronics of the electric motor are located in the power supply adapter.

28. A ventilation fan, comprising:
a fan housing connected with a printed circuit board and having a duct through which air flows;
a fan wheel disposed in the duct for providing the air flow therewithin;
an electric motor coupled to the fan housing for driving the fan wheel;
a plurality of fasteners coupled to at least part of the fan housing for connecting the fan housing with the printed circuit board; and
a power supply adapter connected with the fan housing with the printed circuit board, the adapter supplying power to the electric motor.

29. The fan of claim 28, where the duct comprises a flange that connects with each of the plurality of fasteners and with the power supply adapter.

30. The fan of claim 28, where the connection of the power supply adapter with the printed circuit board comprises a pluggable wrap connection.

31. A fan that ventilates electronic equipment, comprising:
a cylindrical tubular fan housing removeably and replaceably secured to a printed circuit board and having a duct for allowing air to flow, where the duct has a flange formed on a surface thereof;
a fan wheel disposed in the duct, an inner diameter of the fan housing adapted to the radius of the fan wheel;
an electric motor coupled to the fan housing for driving the fan wheel;
a plurality of columnar fasteners coupled to the flange and to the fan housing, where the fasteners connect the fan housing with the printed circuit board; and
a power supply adapter connected with the flange and in pluggable connection with the printed circuit board, the adapter supplying power to the electric motor, where associated electronic components of the electric motor are integrated in the power supply adapter.
